(19) United States
(12) Patent Application Publication
(10) Pub. No.: US 2011/0233603 A1
(43) Pub. Date: Sep. 29, 2011

(54) SEMICONDUCTOR LIGHT-EMITTING DEVICE

(75) Inventors: Chang-Tae Kim, Gyeonggi-do (KR); Gi Yeon Nam, Gyeonggi-do (KR)

(73) Assignee: EPIVALLEY CO., LTD., Gyungbuk (KR)

(21) Appl. No.: 13/132,854

(22) PCT Filed: Dec. 4, 2009
(86) PCT No.: PCT/KR2009/007241

§ 371 Date: Jun. 3, 2011

(30) Foreign Application Priority Data
Dec. 4, 2008 (KR) 1020080122470
Dec. 4, 2009 (KR) PCT/KR09/007241

(51) Int. Cl. H01L 33/62

(52) U.S. Cl. 257/99; 257/E33.062

(57) ABSTRACT

The present disclosure relates to a semiconductor light-emitting device including: a plurality of semiconductor layers having a first semiconductor layer with a first conductivity, a second semiconductor layer with a second conductivity different from the first conductivity, and an active layer interposed between the first semiconductor layer and the second semiconductor layer and generating light by recombination of electrons and holes; a bonding pad electrically connected to the plurality of semiconductor layers; a first electrode spread over the plurality of semiconductor layers; and a second electrode extended from the bonding pad to the first electrode and electrically connecting the bonding pad to the first electrode.

### TECHNICAL FIELD

The present disclosure generally relates to a semiconductor light-emitting device, and, more particularly, to a semiconductor light-emitting device which can prevent a wire-bonded pad from being peeled off.

Here, the semiconductor light-emitting device indicates a semiconductor light-emitting device which generates light by recombination of electrons and holes, and its example is a III-nitride semiconductor light-emitting device. A III-nitride semiconductor is made of a compound containing Al(ₓ)Ga(_{y})In(_{1-x-y})N (0≦x≦1, 0≦y≦1, 0≦x+y≦1). In addition, another example may be a GaAs-based semiconductor light-emitting device for red emission.

### BACKGROUND ART

This section provides background information related to the present disclosure which is not necessarily prior art.

FIG. 1 is a view illustrating one example of a conventional III-nitride semiconductor light-emitting device. The III-nitride semiconductor light-emitting device includes a substrate 100, a buffer layer 200 grown on the substrate 100, an n-type III-nitride semiconductor layer 300 grown on the buffer layer 200, an active layer 400 grown on the n-type III-nitride semiconductor layer 300, a p-type III-nitride semiconductor layer 500 grown on the active layer 400, a p-side electrode 600 formed on the p-type III-nitride semiconductor layer 500, a p-side bonding pad 700 formed on the p-side electrode 600, an n-side electrode 800 formed on the n-type III-nitride semiconductor layer 300 exposed by mesa-etching the p-type III-nitride semiconductor layer 500 and the active layer 400, and a protection film 900.

In the case of the substrate 100, a GaN substrate can be used as a homo-substrate, and a sapphire substrate, an SiC substrate or an Si substrate can be used as a hetero-substrate. However, any type of substrate that can have a III-nitride semiconductor layer grown thereon can be employed. In the case that the SiC substrate is used, the n-side electrode 800 can be formed on the side of the SiC substrate.

The III-nitride semiconductor layers grown on the substrate 100 are mostly grown by metal organic chemical vapor deposition (MOCVD).

The buffer layer 200 serves to overcome differences in lattice constant thermal expansion coefficient between the hetero-substrate 100 and the III-nitride semiconductor. U.S. Pat. No. 5,122,845 describes a technique of growing an AlN buffer layer with a thickness of 100 Å to 500 Å on a sapphire substrate at a temperature of 380° C. to 800° C. In addition, U.S. Pat. No. 5,290,393 describes a technique of growing an Al(ₓ)Ga(₁₋ₓ)N (0≦x≦1) buffer layer with a thickness of 10 Å to 5000 Å on a sapphire substrate at a temperature of 200° C. to 900° C. Moreover, U.S. Laid-Open Patent Publication No. 2006/154454 suggests a technique of growing an SiC buffer layer (seed layer) at a temperature of 600° C. to 990° C. and growing an In(x)Ga(1-x)N (0≦x≦1) thereon. Preferably, an undoped GaN layer is grown prior to the growth of the n-type III-nitride semiconductor layer 300. The GaN layer may be regarded as either a portion of the buffer layer 200 or a portion of the n-type III-nitride semiconductor layer 300.

In the n-type III-nitride semiconductor layer 300, at least the n-side electrode 800 region (n-type contact layer) is doped with a dopant. Preferably, the n-type contact layer is made of GaN and doped with Si. U.S. Pat. No. 5,733,796 describes a technique of doping an n-type contact layer at a target doping concentration by adjusting a mixture ratio of Si and another source material.

The active layer 400 generates light quanta (light) by recombination of electrons and holes. Normally, the active layer 400 contains In(ₓ)Ga(₁₋ₓ)N (0≦x≦1) and has a single quantum well or multi-quantum wells.

The p-type III-nitride semiconductor layer 500 is doped with an appropriate dopant such as Mg and provided with p-type conductivity by an activation process. U.S. Pat. No. 5,247,533 describes a technique of activating a p-type III-nitride semiconductor layer by electron beam irradiation. Moreover, U.S. Pat. No. 5,306,662 describes a technique of activating a p-type III-nitride semiconductor layer by annealing of at least 400° C. U.S. Laid-Open Patent Publication No. 2006/157714 suggests a technique of providing a p-type III-nitride semiconductor layer with p-type conductivity without an activation process, by using ammonia and a hydrazine-based source material together as a nitrogen precursor for growing the p-type III-nitride semiconductor layer.

The p-side electrode 600 is provided to facilitate current supply to the whole p-type III-nitride semiconductor layer 500. U.S. Pat. No. 5,563,422 describes a technique relating to a light-transmitting electrode made of Ni and Au and formed almost on the entire surface of a p-type III-nitride semiconductor layer 500 in ohmic-contact therewith. In addition, U.S. Pat. No. 6,515,306 describes a technique of forming an n-type superlattice layer on a p-type III-nitride semiconductor layer, and then forming a light-transmitting electrode made of ITO thereon.

Meanwhile, the p-side electrode 600 can be sufficiently thick not to transmit but to reflect light toward the substrate. This technique is called a flip chip technique. U.S. Pat. No. 6,194,743 describes a technique relating to an electrode structure including an Ag layer with a thickness of at least 20 Å, a diffusion barrier layer covering the Ag layer, and a bonding layer containing Au and Al and covering the diffusion barrier layer.

The p-side bonding pad 700 and the n-side electrode 800 are provided for current supply and external wire bonding. U.S. Pat. No. 5,563,422 describes a technique of forming an n-side electrode with Ti and Al.

The protection film 900 is made of SiO₂, which can be omitted.

In the meantime, the n-type III-nitride semiconductor layer 300 or the p-type III-nitride semiconductor layer 500 may be composed of a single layer or multiple layers. Recently, suggested is a technique of manufacturing a vertical light-emitting device by removing the substrate 100 from the III-nitride semiconductor layers by laser or wet etching.

However, such a light-emitting device has a problem that the p-side bonding pad 700 may be peeled off from the light-emitting device, when wire bonding is performed on the p-side bonding pad 700.

FIG. 2 is a view illustrating one example of a III-nitride semiconductor light-emitting device disclosed in U.S. Pat. No. 5,563,422. This patent discloses a technique relating to a light-emitting device which is intended to prevent a p-side bonding pad 510 from being peeled off from the light-emitting device, when wire bonding is performed on the p-side bonding pad 510, by directly adhering the p-side bonding pad 510 to a p-type III-nitride semiconductor layer 310. The light-emitting device includes a substrate 110, an n-type III-nitride semiconductor layer 210 formed on the substrate 110, the p-type III-nitride semiconductor layer 310 formed on the n-type III-nitride semiconductor layer 210, a p-side electrode 410 formed on the p-type III-nitride semiconductor layer 310 and having a cut-out portion 412, an n-side electrode 610 formed on the n-type III-nitride semiconductor layer 210 exposed by etching, and the p-side bonding pad 510 formed on the p-side electrode 410 and contacting the p-type III-nitride semiconductor layer 310 through the cut-out portion 412.

However, such a light-emitting device also has a problem that the p-side bonding pad 510 may be peeled off from the light-emitting device, when wire bonding is performed on the p-side bonding pad 510, because of poor adhesion between the p-side bonding pad 510 (for example, metal such as Cr and Au) and the p-side electrode 410 (for example, a conductive oxide film such as ITO),

Moreover, to ensure electrical contact between the p-side bonding pad 510 and the p-side electrode 410, it is necessary that the p-side bonding pad 510 and the p-side electrode 410 should overlap with each other to some extent, which results in a loss of luminous efficiency of the light-emitting device.

### DISCLOSURE

### Technical Problem

The problems to be solved by the present disclosure will be described in the latter part of the best mode for carrying out the invention.

### Technical Solution

This section provides a general summary of the disclosure and is not a comprehensive disclosure of its full scope or all of its features.

According to one aspect of the present disclosure, a semiconductor light-emitting device includes: a plurality of semiconductor layers having a first semiconductor layer with a first conductivity, a second semiconductor layer with a second conductivity different from the first conductivity, and an active layer interposed between the first semiconductor layer and the second semiconductor layer and generating light by recombination of electrons and holes; a bonding pad electrically connected to the plurality of semiconductor layers; a first electrode spread over the plurality of semiconductor layers; and a second electrode extended from the bonding pad to the first electrode and electrically connecting the bonding pad to the first electrode.

### Advantageous Effects

With a semiconductor light-emitting device according to the present disclosure, it is possible to prevent a bonding pad from being peeled off from the light-emitting device upon wire bonding.

In addition, with another semiconductor light-emitting device according to the present disclosure, a bonding pad can be firmly adhered, and current supply to the light-emitting device can be facilitated.

### BRIEF DESCRIPTION OF THE DRAWINGS

FIG. 1 is a view illustrating one example of a conventional III-nitride semiconductor light-emitting device;

FIG. 2 is a view illustrating one example of a III-nitride semiconductor light-emitting device disclosed in U.S. Pat. No. 5,563,422;

FIG. 3 is a view illustrating one example of a III-nitride semiconductor light-emitting device according to the present disclosure;

FIG. 4 is a sectional view illustrating one example of the III-nitride semiconductor light-emitting device according to the present disclosure;

FIG. 5 is a view illustrating one example of a method for manufacturing a III-nitride semiconductor light-emitting device according to the present disclosure; and

FIG. 6 is a photograph of the III-nitride semiconductor light-emitting device according to the present disclosure when emitting light by changes in current.

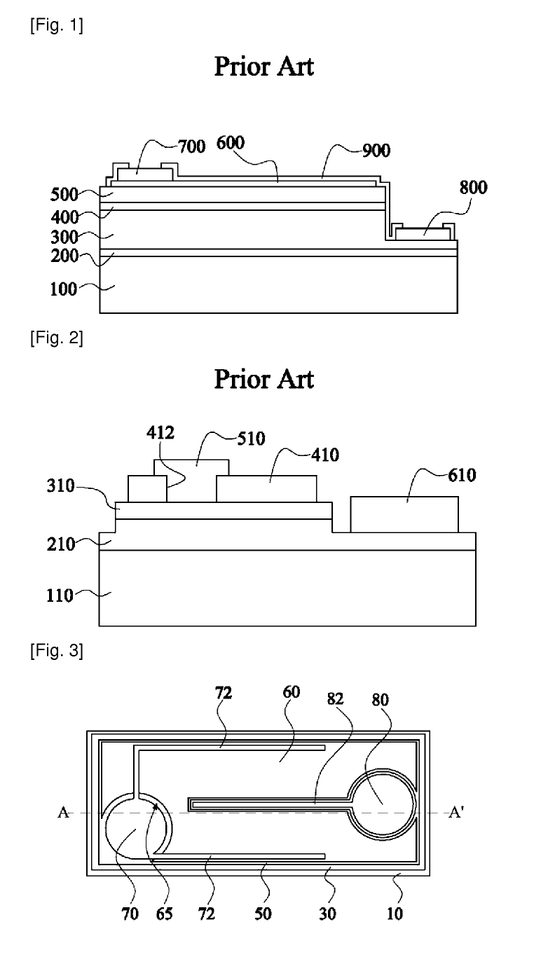

### BEST MODE FOR CARRYING OUT THE INVENTION

The present disclosure will now be described in detail with reference to the accompanying drawings.

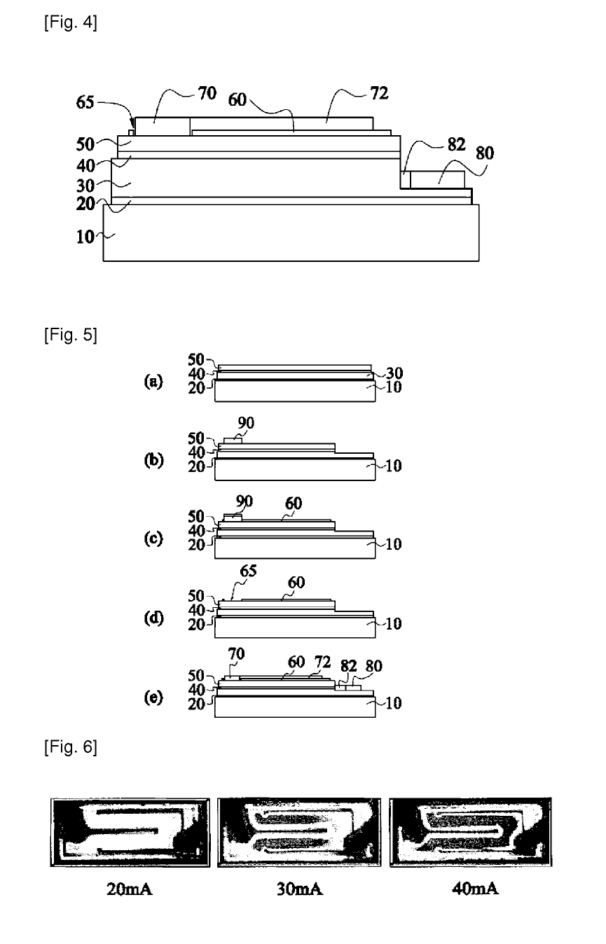

FIGS. 3 and 4 are views illustrating one example of a III-nitride semiconductor light-emitting device according to the present disclosure, in which FIG. 4 is a cross-sectional view taken along line A-A′ of FIG. 3. The light-emitting device includes a substrate 10, a buffer layer 20 grown on the substrate 10, an n-type III-nitride semiconductor layer 30 grown on the buffer layer 20, an active layer 40 grown on the n-type III-nitride semiconductor layer 30, a p-type III-nitride semiconductor layer 50 grown on the active layer 40, an n-side electrode 80 formed on the n-type III-nitride semiconductor layer 30 exposed by etching at least the p-type III-nitride semiconductor layer 50 and the active layer 40, a p-side bonding pad 70, a p-side electrode 60, and branch electrodes 72 and 82.

The p-side bonding pad 70 is formed on the p-type III-nitride semiconductor layer 50, and a wire is bonded to the p-side bonding pad 70 to supply electricity to the light-emitting device. The p-side bonding pad 70 is made of a material with high adhesion to the p-type III-nitride semiconductor layer 50 to be continuously adhered thereto, even when pulled by the wire during or after wire bonding. For example, the p-side bonding pad 70 may be formed at a thickness of about 1.5□ by stacking Cr/Ni/Au.

The p-side electrode 60 serves to facilitate current supply to the whole p-type III-nitride semiconductor layer 50 and is formed on the p-type III-nitride semiconductor layer 50. The p-side electrode 60 may be made of a conductive oxide film. The p-side electrode 60 is provided with a cut-out portion 65 for preventing the p-side bonding pad 70 from being peeled off from the p-type III-nitride semiconductor layer 50 by external force due to low adhesion between the p-side electrode 60 and the p-side bonding pad 70, and thus spaced apart from the p-side bonding pad 70. For example, the p-side electrode 60 may be made of indium tin oxide (ITO) and may have a thickness of about 1750 Å.

The branch electrode 72 is in contact with the p-side bonding pad 70 and the p-side electrode 60. As such, current supplied to the p-side bonding pad 70 is supplied to the p-side electrode 60 through the branch electrode 72, so that current supply to the whole p-type III-nitride semiconductor layer 50 can be facilitated while strong adhesion is maintained between the p-side bonding pad 70 and the p-type III-nitride semiconductor layer 50. For this purpose, the branch electrode 70 is extended from the p-side bonding pad 70 above the _{A}-side electrode 60. For example, the branch electrode 72 may be formed at a thickness of about 1.5□ by stacking Cr/Ni/Au.

Hereinafter, one example of a method for manufacturing a III-nitride semiconductor light-emitting device according to the present disclosure will be described.

FIG. 5 is a view illustrating one example of the method for manufacturing the III-nitride semiconductor light-emitting device according to the present disclosure.

First, a buffer layer 20, an n-type III-nitride semiconductor layer 30, an active layer 40, and a p-type III-nitride semiconductor layer 50 are grown on a substrate 10 (see (a) of FIG. 5).

Next, the p-type III-nitride semiconductor layer 50 and the active layer 40 are etched to expose the n-type III-nitride semiconductor layer 30 so that an n-side electrode 80 can be formed thereon (see (b) of FIG. 5).

Next, the formation of a p-side electrode 60 having a cut-out portion 65 can be done by photolithography, i.e., by forming a photoresist 90 on the p-type III-nitride semiconductor layer 50 except for the expected region of the p-side electrode 60 (see (b) of FIG. 5), depositing the p-side electrode 60 on the p-type III-nitride semiconductor layer 50 (see (c) of FIG. 5), and removing the photoresist 90 (see (d) of FIG. 5). The p-side electrode 60 may be formed before the etching process for exposing the n-type III-nitride semiconductor layer 30.

Meanwhile, in order to form the p-side electrode 60 having the cut-out portion 65, the formation of the cut-out portion 65 can be done by forming the p-side electrode 60 on the p-type III-nitride semiconductor layer 50, forming an etching mask (not shown) on the p-side electrode 60 so as to expose the expected region of the cut-out portion 65, and removing the p-side electrode 60 exposed by the etching mask (not shown) by wet etching. For instance, if the p-side electrode 60 is made of ITO, wet etching can be done by immersing the p-side electrode 60 in a solution containing HCl at about 45□ for about 30 seconds.

Next, a p-side bonding pad 70 is formed on the p-type III-nitride semiconductor layer 50 exposed by the cut-out portion 65 (see (e) of FIG. 5). At the same time, the branch electrode 72 is formed, e.g., by a separate process. For example, the p-side bonding pad 70 may be formed at a thickness of about 1.5□ by sequentially stacking Cr, Ni and Au layers by electron beam deposition. The n-side electrode 80 and the branch electrode 82 can be formed in the same manner as above.

FIG. 6 is a photograph of the III-nitride semiconductor light-emitting device according to the present disclosure when emitting light by changes in current. It can be seen that light is uniformly emitted from the entire light-emitting device because current is smoothly diffused to the p-side electrode 60 (see FIG. 3) in the configuration where the branch electrode 72 (see FIG. 3) is connected to the p-side bonding pad 70 (see FIG. 3) and the p-side electrode 60 (see FIG. 3).

Hereinafter, various embodiments of the present disclosure will be described.

(1) A semiconductor light-emitting device including a p-side electrode having a cut-out portion so that a p-side bonding pad and the p-side electrode can be spaced apart. With this construction, it is possible to prevent the p-side bonding pad from being peeled off from the light-emitting device by external force during wire bonding due to low adhesion between the p-side bonding pad and the p-side electrode. It should be noted that partial overlaps between the p-side bonding pad and the p-side electrode may exist in a branch electrode formation region extended from the p-side bonding pad.

(2) A semiconductor light-emitting device including a branch electrode extended from a p-side bonding pad and brought into contact with a p-side electrode. With this construction, current can be supplied from the p-side bonding pad to the p-side electrode.

1. A semiconductor light-emitting device, comprising:
a plurality of semiconductor layers having a first semiconductor layer with a first conductivity, a second semiconductor layer with a second conductivity different from the first conductivity, and an active layer interposed between the first semiconductor layer and the second semiconductor layer and generating light by recombination of electrons and holes;
a bonding pad electrically connected to the plurality of semiconductor layers;
a first electrode spread over the plurality of semiconductor layers; and
a second electrode extended from the bonding pad to the first electrode and electrically connecting the bonding pad to the first electrode.

2. The semiconductor light-emitting device of claim 1, wherein the first electrode is spaced apart from the bonding pad.

3. The semiconductor light-emitting device of claim 1, comprising a third electrode formed on the first semiconductor layer exposed by etching at least the second semiconductor layer and the active layer.

4. The semiconductor light-emitting device of claim 1, wherein the bonding pad is formed on the second semiconductor layer, and the first electrode is formed on the second semiconductor layer and spaced apart from the bonding pad; and
wherein the light-emitting device comprises:
a third electrode formed on the first semiconductor layer exposed by etching at least the second semiconductor layer and the active layer; and
a fourth electrode extended from the third electrode.

5. The semiconductor light-emitting device of claim 1, wherein the light-emitting device is a III-nitride semiconductor light-emitting device.
